(19) United States
(12) Patent Application Publication
(10) Pub. No.: US 2009/0061632 A1
(43) Pub. Date: Mar. 5, 2009

(54) METHODS FOR CLEANING ETCH RESIDUE DEPOSITED BY WET ETCH PROCESSES FOR HIGH-K DIELECTRICS

(75) Inventor: Scott R. Summerfelt, Garland, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 12/180,179

(22) Filed: Jul. 25, 2008

Related U.S. Application Data
(60) Provisional application No. 60/968,439, filed on Aug. 28, 2007.

(51) Int. Cl. H01L 21/311

(52) U.S. Cl. 438/694; 257/E21.219

(57) ABSTRACT

A method (100) of fabricating a device having at least one multi-cation high-k dielectric layer structure includes (101) providing a substrate having a semiconductor surface, (102) forming a multi-cation high-k dielectric layer on the semiconductor surface, and (103) forming a patterned masking layer including at least one masking layer region on the multi-cation high-k dielectric layer. A first wet etch process (104) removes at least a portion of the multi-cation high-k layer outside the patterned masking layer region, wherein at least one residual etch particle type is deposited on a surface of the substrate outside the patterned masking layer region. The method further includes a cleaning step that includes at least one of (105) (i) a second wet etch process after the first wet etching process, wherein the first and the second etch process both include at least one common etchant and an etch rate of the multi-cation high-k dielectric layer during the second etch process is ≦5% of the etch rate during the first etch process (104), and (ii) a dry cleaning process (205, 305) after the first wet etching process (104) for reducing a concentration of the residual etch particle type.

### FIELD OF THE INVENTION

The present invention relates to discrete device, integrated circuit and MEMS processing, and more specifically to methods for reducing etch residuals deposited by wet etching high-k dielectrics.

### BACKGROUND

When possible, wet etching is generally preferred over dry etching based primarily on cost considerations. Applications for wet etching are generally limited by undercut considerations that result from the isotropic nature of wet etch that results in the lateral etch rate being roughly the same as the vertically etch rate. As a result, applications for wet etching generally involve a minimum feature size that is roughly ≧3× greater than the layer thickness being etched. Wet etching is also generally known to provide the advantage of improved selectivity over dry etching.

One class of dielectrics is high dielectric constant dielectrics, referred to as high-k dielectrics. As known in the art, a vacuum is the reference point for the dielectric constant and has a k-value equal to 1, while air has a k-value of slightly over 1. A sub-class of high-k dielectrics is high dielectric constant multi-cation materials (hereafter multi-cation high-k dielectrics), which comprise a plurality of different cations. Exemplary multi-cation high-k dielectrics include Pb(Zr,Ti)O₃ (PZT), doped PZT (with dopants selected from La, Nb, Mn, and Ta), SrPbTiO₃, and (Ba,Sr)TiO₃. Some multi-cation high-k dielectrics are non-ferroelectric, and some may be piezoelectric. Multi-cation high-k dielectrics as defined herein are materials that comprise a plurality of different cations and provide a k-value≧50.

One problem associated with wet etching multicomponent high-k dielectric materials is that the wet etch generally results in the deposition of an undesirable concentration of residual particles. The residual particles can have poor adhesion to layers subsequently deposited thereon and/or high contact resistance to electrically conductive surfaces.

### SUMMARY

This Summary is provided to comply with 37 C.F.R. §1.73, presenting a summary of the invention to briefly indicate the nature and substance of the invention. It is submitted with the understanding that it will not be used to interpret or limit the scope or meaning of the claims.

Embodiments of the present invention describe cleaning methods to minimize the residue generated by wet etching a patterned multi-cation high-k dielectric layer, remove the residue, ort minimize the impact of the residue by converting it to a different material that has better adhesion properties. Although generally described individually, these methods may generally be combined with one another.

A method of fabricating a device having at least one multi-cation high-k dielectric layer comprising structure comprises providing a substrate having a semiconductor surface, forming a multi-cation high-k dielectric layer on the surface, and forming a patterned masking layer including at least one masking layer region on the multi-cation high-k dielectric layer. A first wet etch process is used to remove at least a portion of the multi-cation high-k layer outside the masking layer region, wherein at least one residual etch particle type is deposited on a surface of the substrate outside the masking layer region during the wet etch. The method further comprises a cleaning step that reduces the density of the residual etch particle type. The cleaning step comprises at least one of process (i) and process (ii) below:

(i) a second wet etch process after the first etch process. In the case of a two (2) etch sequence the first etch process can be an initial etch process and the second etch process can be the final etch process. The first and the second etch process include at least one common etchant, and an etch rate of the multi-cation high-k dielectric layer during the second etch process is ≦5% of the etch rate during the first wet etch process, and

(ii) a dry cleaning process performed after the first wet etch process for reducing a concentration of the residual etch particle type.

### BRIEF DESCRIPTION OF THE DRAWINGS

FIG. 1 is flow diagram for a wet cleaning method for reducing etch residual that is deposited by wet etching multi-cation high-k dielectrics, according to an embodiment of the invention.

FIG. 2 is a flow diagram for a first dry cleaning method for reducing etch residual that is deposited by wet etching multi-cation high-k dielectrics, according to another embodiment of the invention.

FIG. 3 is a flow diagram for a second dry cleaning method for reducing etch residual that is deposited by wet etching multi-cation high-k dielectrics, according to yet another embodiment of the invention.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Embodiments of the invention describe methods for fabricating a device structure having at least one multi-cation high-k dielectric layer. The device can comprise an integrated circuit (IC), one or more discrete components (e.g. capacitor), or a MEMS device. The multi-cation high-k dielectric layer is etched using a process comprising at least one wet etch process. The etch residue (e.g. metal comprising particles) deposited on the substrate during the wet etch process is reduced by a cleaning process according to an embodiment of the invention which can comprise a removal process, or a conversion process that converts the etch residue to a material that provides improved mechanical properties.

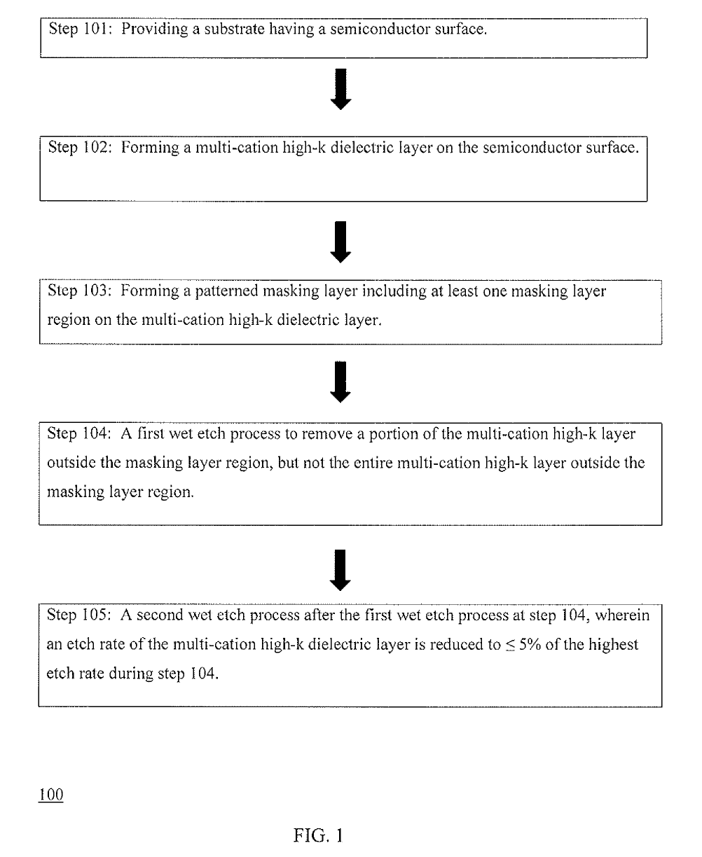

Referring to FIG. 1, a flow diagram is shown for a wet cleaning method 100 for reducing/minimizing etch residual deposited by wet etching multi-cation high-k dielectric, according to an embodiment of the invention. In step 101, a substrate having a semiconductor surface (e.g. Si) is provided. In step 102, a multi-cation high-k dielectric layer is formed on the semiconductor surface, using any suitable method. The multi-cation high-k dielectric layer can comprise an oxide, for example, Pb(Zr,Ti)O₃ (PZT), doped PZT (with dopants selected from La, Nb, Mn, and Ta), SrPbTiO₃, and (Ba,Sr)TiO₃.

Step 103 comprises forming a patterned masking layer including at least one masking layer region on the multi-cation high-k dielectric layer. The masking material defining the masking region can comprise photoresist, or a hard mask material. In one embodiment, the patterned masking layer comprises a plurality of masking layer regions. The concentration of wet etch residue is generally higher near the edge of the masking layer region or masking layer regions. In the case the patterned masking layer comprises a plurality of masking layer regions, the concentration of wet etch residue can be higher, particularly in gaps defined by relatively closely spaced masking layer regions, such masking layer regions spaced less than 20 μm apart in one embodiment of the invention.

Step 104 comprises a first wet etch process to remove a portion of the multi-cation high-k layer outside the masking layer region, but not the entire multi-cation high-k layer outside the masking layer region. In the case of a multi-cation high-k dielectric oxide, the etch solution normally includes deionized (DI) water and a fluorine comprising material, such as HF or NH₄F. The etch solution can also include, for example, nitric acid, phosphoric acid, sulfuric acid or hydrogen peroxide. In one embodiment, a particular etch solution comprises 0.1% HF, 5% HCl and the balance DI water, which generally provides a PET etch rate of about 2 kA/min at 25° C. During the wet etch step, at least one residual etch particle type may be deposited on a surface of the substrate outside the masking region; such as PbF in the case a fluorine comprising etch solution for etching PZT. The etch step 104 is generally performed at roughly room temperature, or at a slightly elevated temperature (e.g. 25 to 45° C.).

The cleaning process in step 105 comprises a second wet etch process that takes place subsequent to the first wet etch process at step 104. Etch step 105 is generally performed at roughly room temperature, or at a slightly elevated temperature. An etch rate of the multi-cation high-k dielectric layer during at least a portion of step 105 is reduced to ≦5% of the etch rate or highest etch rate during step 104. The significant etch rate reduction for step 105 can be accomplished, for example, by reducing (diluting) at least one etchant in the etchant solution, and/or changing one of more of the etchant chemicals. In the case of three (3) or more etch processes, one of the etch processes can comprise a change in temperature only as compared to the previous etch process. In one embodiment of the invention, step 105 comprises using at least one successively less concentrated solution, such as two (2) or three (3) successively less concentrated solutions. In another embodiment, a gradual concentration reduction is used, such as a linear reduction. The relatively high etch rate of the first etch process (step 104), which can generally comprise 30% to 98% of the total combined etch time, allows the total etch time for method 100 to be sufficiently short to be reasonable for manufacturing, while the reduced etch rate of step 105 has been found to significantly reduce the concentration of the etch residual(s). When using lower concentrations of etch solution to achieve the lower etch rate, the concentrations should generally be strong enough to remove the etch residue from the substrate surface and thus put the etch residue into solution, but not materially etch more multi-cation high-k dielectric (e.g. etch rate of <1 A/second).

In one embodiment, the respective etch processes (steps 104 and 105) can be performed in separate tanks where each tank has a different etch solution. In one example, a multi-cation high-k etch solution comprising a first etchant at X concentration is used in a first tank to etch the multi-cation high-k dielectric, then in a second tank a 10% X concentration is used to etch the multi-cation high-k dielectric, then a 1% X concentration in a third tank is used to etch the multi-cation high-k dielectric.

In another embodiment, steps 104 and 105 are performed in a spray processing system. Concentration changes are facilitated in the spray processing system, where the solution concentration may be microprocessor controlled using liquid flow controllers and DI water.

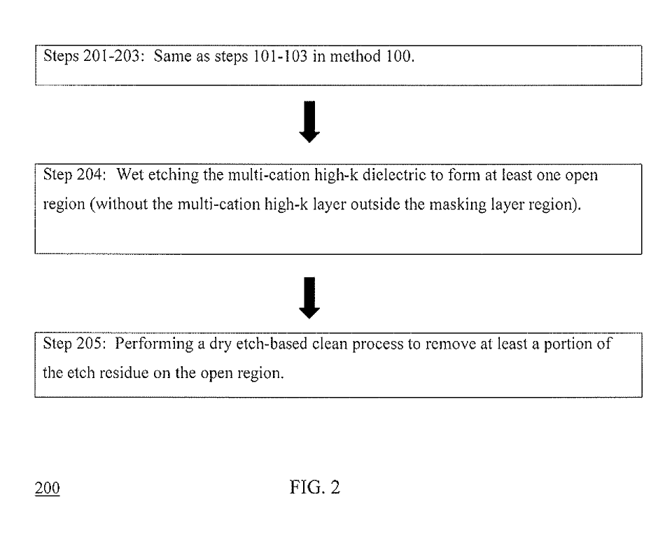

FIG. 2 is a flow diagram for a first dry cleaning process-based method 200 for reducing etch residual that is deposited by wet etching multi-cation high-k dielectrics, according to another embodiment of the invention. In method 200, steps 201-203 include steps 101-103. Step 204 comprises a wet etch process for etching the multi-cation high-k dielectric layer to form open regions without the multi-cation high-k layer outside the masking region, wherein at least one residual etch particle type is deposited on a surface of the exposed surface outside the masking region. Step 205 comprises a dry etch-based clean process that is generally performed to remove the wet etch residue before removing the masking layer (e.g. photoresist). The dry clean can comprise a sputter etch (Ar for example), or a conventional dry etch process, such as a plasma-based process. Since only wet etch residue is being removed in method 200, method 200 is generally a less expensive process as compared to a dry etch of the entire multi-cation high-k layer. In one embodiment, the sputter etch is performed in the chamber of a thin film deposition tool prior to deposition of the needed film. The thin film deposition system can comprise a metal sputtering, high density plasma (HDP), or a plasma enhanced dielectric deposition system. For example, an Ar sputter etch uses RF plasma at the chuck using a typical plasma generated by an RF signal at approximately 13.56 MHz.

Since such systems already generally include RF-based plasma generators, there is generally no need for additional equipment, and the addition of the dry clean can be performed in-situ in the same chamber as a preceding step to the thin film deposition. Dielectric layer deposition can follow the high-k feature formation in some process flows. The deposition system can provide a dielectric layer comprised of an oxide (e.g. TEOS) or a nitride (e.g. SiN).

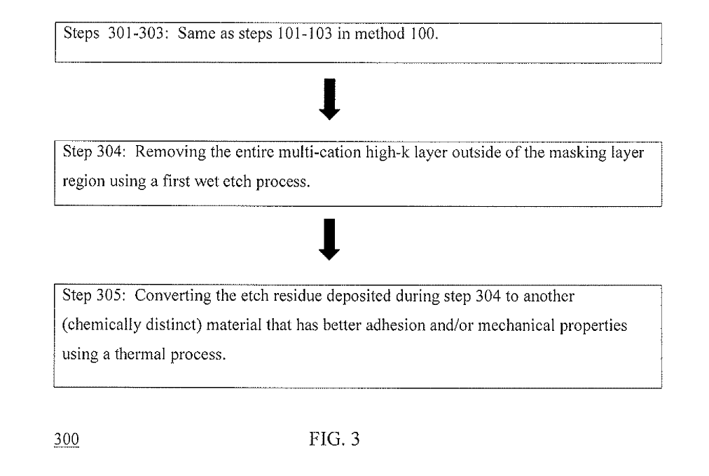

FIG. 3 is a flow diagram for a second dry cleaning process-based method 300 for reducing etch residual that is deposited by wet etching multi-cation high-k dielectrics, according to yet another embodiment of the invention. In method 300, steps 301-303 include steps 101-103. Step 304 is step 104 modified to remove the entire multi-cation high-k layer outside of the masking layer region. Step 305 of method 300 converts the etch residue deposited during step 304 on the substrate surface to another (chemically distinct) material that has better adhesion and/or mechanical properties as compared to the etch residue. As noted above, the wet etch residue is generally a hydroxide or other solution compound. One embodiment comprises converting the residue after removing the masking layer (in the case of photoresist) to another material that is more robust for adhesion and/or for low resistance electrical contacts. One method uses a heat step, such as a furnace anneal or a rapid thermal anneal (RTA).

In one embodiment, the heat step can convert the residue to a dense ceramic. When the masking layer is an organic masking layer (e.g. photoresist), the masking layer is generally removed before the conversion step. An advantage of this method is that the remaining multi-cation high-k dielectric degraded (e.g. damaged) by the wet etch process can be improved. The improvement can arise because of the additional thermal process which can reduce the damage that is known to be sometimes pronounced near the edges of the multi-cation high-k features. Some exemplary anneals are furnace anneal (15 min to 60 min) at 500 to 650° C. in N₂ or O₂ at 1 atm. RTA anneals can be at 550° C. to 700° C. for 30 sec to 2 min in N₂ or O₂.

Embodiments of the invention can be integrated into a variety of process flows. In the case of the formation of FE (e.g. ferroelectric) capacitors, the method can comprise bottom electrode deposition, multi-cation high-k deposition, and then top electrode deposition. The bottom and top electrode can comprise Ir. The top electrode can be dry etched, followed by a method according to an embodiment of the invention for wet etching the multi-cation high-k dielectric followed by a wet or dry cleaning of the wet etch deposited residual. The bottom electrode is then dry etched.

Embodiments of the invention can be integrated into a variety of process flows to form a variety of devices and related products. Exemplary devices and products include high breakdown voltage capacitors, MEMS devices that include piezoelectrics, vibrational energy harvesters, resonators, activators, microphones and ink-jets.

The semiconductor substrates may include various elements therein and/or layers thereon. These can include barrier layers, other dielectric layers, device structures, active elements and passive elements including, source regions, drain regions, bit lines, bases, emitters, collectors, conductive lines, conductive vias, etc. Moreover, the invention can be using in a variety of processes including bipolar, CMOS, BiCMOS and MEMS.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

What is claimed is:

1. A method of fabricating a device having at least one multi-cation high-k dielectric layer structure, comprising:
providing a substrate having a semiconductor surface;
forming said multi-cation high-k dielectric layer on said semiconductor surface;
forming a patterned masking layer comprising at least one masking layer region on said multi-cation high-k dielectric layer;
a first wet etch process to remove at least a portion of said multi-cation high-k dielectric layer outside said patterned masking layer region, wherein at least one residual etch particle type is deposited on a surface of said substrate outside said patterned masking layer region during said first wet etch process, and
wherein said method further comprises a cleaning step, said cleaning step comprising at least one of:
(i) a second wet etch process after said first wet etch process, wherein said first and said second wet etch processes both include at least one common etchant and an etch rate of said multi-cation high-k dielectric layer during said second wet etch process is ≦5% of a highest etch rate during said first etch process, and
(ii) a dry cleaning process after said first wet etch process for reducing a concentration of said residual etch particle type.

2. The method of claim 1, wherein said multi-cation high-k dielectric layer comprises an oxide.

3. The method of claim 2, wherein said oxide is selected from the group consisting of Pb(Zr,Ti)O₃ (PZT), doped PZT (with dopants selected from La, Nb, Mn, and Ta), SrPbTiO₃, and (Ba,Sr)TiO₃.

4. The method of claim 1, wherein said at least one common etchant comprises a first and a second common etchant, wherein a concentration of said first and said second common etchant in said second wet etch process are both ≧0 but less than respective concentrations of said first and said second common etchant during said first wet etch process.

5. The method of claim 4, wherein said first common etchant comprises HF or NH₄F and said second common etchant comprises HCl.

6. The method of claim 4, wherein said first and said second wet etch processes are performed in a spray acid processor.

7. The method of claim 1, wherein said dry cleaning process comprises a sputter-based process or a plasma-based process.

8. The method of claim 1, wherein said dry cleaning is performed before removing said patterned masking layer.

9. The method of claim 7, wherein said plasma-based process comprises a plasma etch.

10. The method of claim 7, wherein said sputter-based process comprises a sputter etch, said sputter etch performed in a chamber of a thin film deposition system, said chamber used to deposit a thin film in-situ subsequent to said sputter etch dry cleaning step.

11. The method of claim 10, wherein said thin film deposition system comprises a plasma enhanced dielectric deposition system, and said thin film comprises a dielectric thin film.

12. The method of claim 1, wherein said dry cleaning comprises a chemical conversion process at a temperature of between 500° C. and 800° C. for converting said residual etch particle type to another material.

13. The method of claim 12, wherein said dry cleaning process comprises a furnace anneal or a rapid thermal anneal (RTA).

14. The method of claim 12, wherein an ambient for said chemical conversion process comprises primarily N₂ or O₂ and said another material comprises a ceramic.

15. The method of claim 1, wherein said at least one patterned masking layer region comprises a plurality of said masking layer regions.

16. A method of fabricating a multi-cation high-k dielectric layer structure in a semiconductor device, comprising:
providing a substrate wafer having a semiconductor surface;
forming said multi-cation high-k dielectric layer on said semiconductor surface;
forming a patterned masking layer comprising at least one masking layer region on said multi-cation high-k dielectric layer;
a first wet etch process to remove at least a portion of said multi-cation high-k dielectric layer outside said patterned masking layer region, wherein at least one residual etch particle type is deposited on a surface of said substrate outside said patterned masking layer region during said first wet etch process, and
wherein said method further comprises a cleaning step, said cleaning step comprising at least one of:
(i) a second wet etch process after said first wet etch process, wherein said first and said second wet etch processes both include at least one common etchant and an etch rate of said multi-cation high-k dielectric layer during said second wet etch process is ≦5% of a highest etch rate during said first etch process, and
(ii) a dry cleaning process after said first wet etch process for reducing a concentration of said residual etch, and
completing fabrication of said semiconductor device.

17. The method of claim 16, wherein said multi-cation high-k dielectric layer comprising structure comprises a capacitor and said semiconductor device comprises an integrated circuit (IC).

18. The method of claim 16, wherein said at least one patterned masking layer region comprises a plurality of said masking layer regions.
